(19) United States
(12) Patent Application Publication
(10) Pub. No.: US 2018/0073160 A1
(43) Pub. Date: Mar. 15, 2018

(54) ELECTROPLATING APPARATUS, ELECTROPLATING METHOD, AND MANUFACTURING METHOD OF SEMICONDUCTOR DEVICE

(71) Applicant: KABUSHIKI KAISHA TOSHIBA, Minato-ku (JP)

(72) Inventor: Kazuhito HIGUCHI, Yokohama (JP)

(73) Assignee: KABUSHIKI KAISHA TOSHIBA, Minato-ku (JP)

(21) Appl. No.: 15/699,247

(22) Filed: Sep. 8, 2017

(30) Foreign Application Priority Data
Sep. 9, 2016 (JP) 2016-176815

(51) Int. Cl. C25D 17/12; C25D 5/04; C25D 7/12; C25D 5/02; C25D 17/06; C25D 21/14; C25D 3/38; C25D 17/02; C25D 5/00; H01L 21/288

(52) U.S. Cl. CPC C25D 17/12; C25D 5/04; C25D 7/123; C25D 5/022; H01L 21/2885; C25D 21/14; C25D 3/38; C25D 17/02; C25D 5/003; C25D 17/06

(57) ABSTRACT

According to one embodiment, an electroplating method includes, arranging an anode having passages through which a plating solution flows and a cathode to face each other via a resist mask, in a reaction section storing the plating solution, and setting a potential of the cathode to a negative potential to the anode, to form a metal plated film on the surface of the cathode.

### CROSS-REFERENCE TO RELATED APPLICATIONS

This application is based upon and claims the benefit of priority from the prior Japanese Patent Application No. 2016-176815, filed Sep. 9, 2016 the entire contents of which are incorporated herein by reference.

### FIELD

Embodiments of the present invention relate to an electroplating apparatus, an electroplating method, and a manufacturing method of a semiconductor device.

### BACKGROUND

In recent years, information processing technologies are developed and spread, which fact advances miniaturization, thickness reduction and performance improvement of electronic devices, and consequently semiconductor packages also tend to be miniaturized. In particular, the semiconductor packages of about several to 100 pins which are often used in portable terminals and the like are changed from conventional SOP (small out-line packages) and QFP (quad flat packages) to smaller non-lead types of SON (small out-line non-lead packages) and QFN (quad flat non-lead packages). In recent years, these packages are changing to further smaller types of WCSP (wafer-level chip scale packages).

In the general WCSP, solder balls are formed in a latticed manner on a lower surface of each package, and the package is coupled onto substrate electrodes via the solder balls.

A manufacturing process of packages such as the SOP, QFP, SON or QFN has a step of mounting individually diced semiconductor chips in a lead frame, a step of coupling by wire bonding, a step of molding with a sealing resin, a step of cutting off the lead, and a step of plating the exterior of the lead.

On the other hand, a manufacturing process of the WCSP has a preliminary step of dicing a wafer in the form of semiconductor chips, that is, only mounting the solder balls on the surface of the semiconductor wafer followed by dicing in the form of the individual chips, and hence the process has a remarkably high productivity.

In the WCSP, to convert an arrangement of an anelectrode pad of the chip to an arrangement of the solder balls, it is necessary to form a rewire by a semi additive method in which Cu electroplating is used. The semi additive method is constituted of five steps of forming a seed layer which becomes a cathode during electroplating, forming a resist layer by patterning a rewire form, plating Cu by the electroplating, peeling off the resist layer, and etching the seed layer.

These steps are positioned between a previous step of BEOL (back end of line) and a post step in consideration of processes and dimension, and hence they are called intermediate steps. In the intermediate steps, a wafer process is used, and thus as a mass production apparatus, a similar apparatus for use in the BEOL is used.

Specifically, in the formation of the seed layer, for example, laminated thin films of Ti and Cu are used, and for the formation of these films, there is used a sputtering apparatus to form the metal thin films on a wafer. Furthermore, in the formation of the resist layer, a coater/developer and a stepper exposure apparatus are used which automatically perform resist coating, baking, developing, washing and drying.

In an electroplating apparatus, it is necessary to energize the seed layer on the surface of the wafer, and hence a sheet type apparatus is used to mount the wafers one by one in a holder and to form a contact for the energization. In a usual electroplating apparatus, a space between the wafer on which the seed layer functioning as the cathode is formed and an anode is set to be as large as possible for improvement of film thickness uniformity of a plated film. A distance of the space is at least 1 mm, and usually 10 mm or more. Furthermore, there are required three steps of a pretreatment step to remove oxides from the surface of the seed layer, a Cu plating step and a washing/drying step. For the purpose of preventing mutual contamination between the steps, an apparatus is used which separately has treatment tanks for the respective steps and includes an automatic conveying device between the tanks.

On the other hand, subsequently in a peeling apparatus of the resist layer and an etching apparatus of the seed layer, a batch type apparatus to simultaneously treat the wafers is also usable only for a treatment of immersing the wafers into a peeling liquid or an etching liquid, in addition to the sheet type apparatus. In this case, for the purpose of preventing mutual contamination between the treatments similarly to the plating apparatus, there is used an apparatus having rinse tanks separately in addition to the respective treatment tanks, and including automatic conveying devices between the tanks.

By a series of steps in which the apparatuses are used, it is possible to form a wire which has a minimum linear width of 10 μm or less, or a wire in which an aspect ratio which is a ratio of a wire height to the wire width is 0.5 or more. In addition, Cu having a low resistivity is usable as a plating material, and it is possible that both of a high wire density and a low electric resistance coexist.

On the other hand, the series of apparatuses have a high treatment ability of several thousand wafers/month or more, but any of the apparatuses is remarkably expensive and requires a large installation space, as compared with a usual post-process apparatus such as a wire bonding apparatus or a die bonding apparatus. Therefore, an initial investment amount is large, it is difficult to apply the series of apparatuses to products of small quantities but many kinds, and it is also difficult to flexibly cope with changes of a production quantity.

As described above, in case of the production of the WCSP, a floor area to install a large scale production apparatus and the high initial investment are required, and hence it is actually difficult to apply the WCSP to products of the small quantities but many kinds which do not counterbalance the requirements. Especially, in the series of steps, the steps of resist formation, exposure, development and peeling which are concerned with resist, occupy a half or more of all the steps, and these steps are indirect because materials for use and the like do not remain as materials constituting the final product. Therefore, a process is being developed to simplify these steps concerned with the resist, for productivity improvement and cost reduction.

For example, a technology is known in which metal nanopaste is discharged by an ink jet method and a metal wire pattern is formed on a substrate without using the resist. According to this technology, a wire having a thickness of 2 μm, a minimum linear width of about 30 μm and a pitch of about 60 μm can directly be drawn to be formed on the substrate by use of a material such as silver or copper.

However, in the present method, the nanopaste having small viscosity is used, and hence it is considered that interaction with the substrate surface has strong influence and that it is difficult to stably form a minute pattern. Furthermore, there is a limit to a thickness of the wire, and it is difficult to form a wire pattern having an aspect ratio in excess of 0.5. Furthermore, the wire is formed by sintering the nanopaste. Therefore, the wire is different from a complete bulk-like metal in properties, and the wire has lower electric resistance, lower elongation percentage and lower tensile strength than a bulk material. Consequently, there is the problem that the wire has lower electric properties and lower reliability than a conventional wire formed by the semi additive method using the conventional electroplating.

### BRIEF DESCRIPTION OF THE DRAWING

FIG. 1 is an explanatory view showing a schematic constitution of an electroplating apparatus according to a first embodiment;

FIG. 2 is an explanatory view showing a schematic constitution of a part of the electroplating apparatus according to the embodiment;

FIG. 3 is a perspective view showing a constitution of an anode of the electroplating apparatus;

FIG. 4 is an explanatory view showing a current distribution in a cathode of the electroplating apparatus;

FIG. 5 is an explanatory view showing one example of a semiconductor device to be manufactured by an electroplating method according to the embodiment;

FIG. 6 is an explanatory view showing a schematic constitution of an electroplating apparatus according to a second embodiment;

FIG. 7 is an explanatory view showing a schematic constitution of a part of the electroplating apparatus according to the embodiment; and

FIG. 8 is an explanatory view showing a current distribution in a cathode of the electroplating apparatus.

### DETAILED DESCRIPTION

According to one embodiment, an electroplating method comprises, arranging an anode having passages through which a plating solution flows and a cathode to face each other via a resist mask, in a reaction section storing the plating solution, and setting a potential of the cathode to a negative potential to the anode, to form a metal plated film on the surface of the cathode.

### First Embodiment

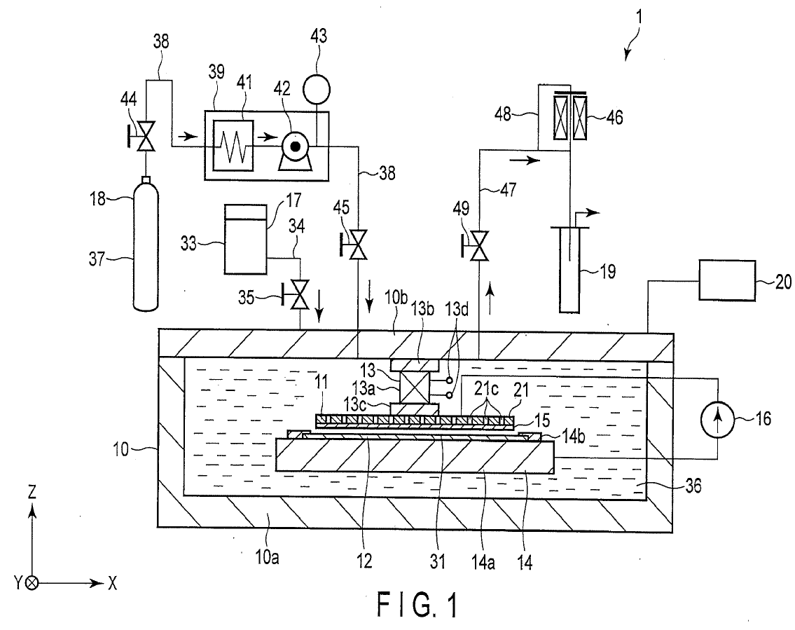

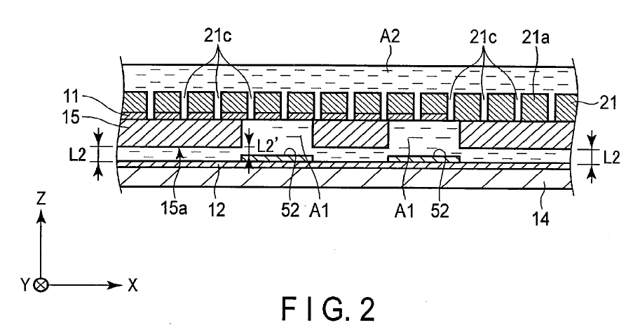

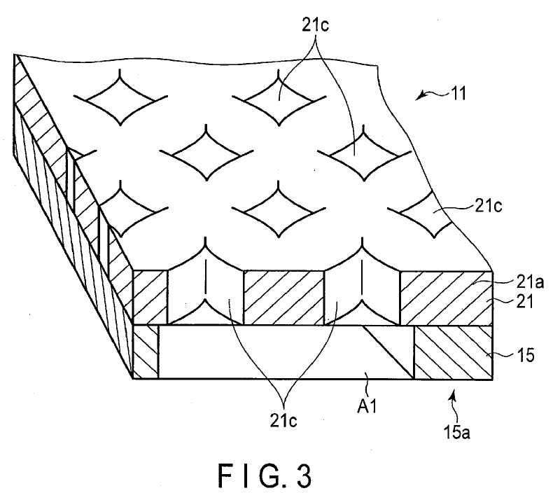

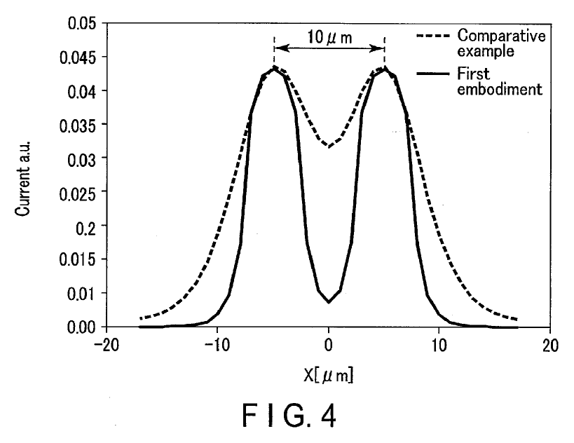

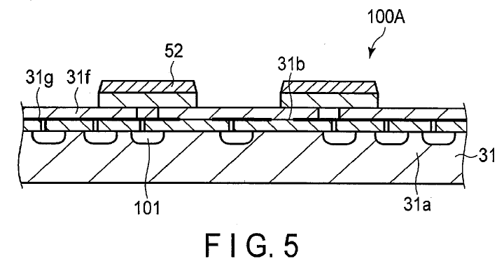

Hereinafter, a manufacturing method of a semiconductor device or a wire substrate by use of an electroplating apparatus 1 and an electroplating method according to a first embodiment will be described with reference to FIG. 1 to FIG. 5. In each drawing, a constitution is enlarged, reduced or omitted suitably for the description. FIG. 1 is an explanatory view showing a schematic constitution of the electroplating apparatus 1 according to the present embodiment. FIG. 2 is an explanatory view showing a schematic constitution of a part of the electroplating apparatus. FIG. 3 is a perspective view showing a constitution of a part of an anode plate of the electroplating apparatus 1. FIG. 4 is an explanatory view showing a current distribution in a cathode of the electroplating apparatus. FIG. 5 is an explanatory view showing one example of the semiconductor device to be manufactured by the electroplating method according to the present embodiment.

In the present embodiment, as one example, there will be described an example where a plating solution 36 is mixed with supercritical CO₂ to form a Cu wire as a plated film 52 on a cathode plate 31 which is made of Si or the like and in which semiconductor elements 101 are formed as shown in FIG. 5, to manufacture a semiconductor device 100A such as a WCSP. It is to be noted that by use of a cathode which do not include the semiconductor elements 101 as the cathode plate 31, the wire substrate can be manufactured by a similar method.

As shown in FIG. 1, the electroplating apparatus 1 according to the present embodiment comprises a reaction tank 10 of a reaction section storing the plating solution 36, an anode 11 disposed in the reaction tank 10, a cathode 12 disposed to face the anode 11, an anode supporter 13 supporting the anode 11, a cathode supporter 14 supporting the cathode 12, a resist mask 15 interposed between the anode 11 and the cathode 12, a direct constant current source 16 for energization, a supercritical fluid supply section 18 coupled to a supply side of the reaction tank 10 via a fluid supply pipe 38, a plating solution supply section 17 coupled to the supply side of the reaction tank 10 via a liquid supply pipe 34, a treatment container 19 coupled to a discharge side of the reaction tank 10 via a discharge pipe 47, and a control section 20 that controls operations of the respective components.

The reaction tank 10 is constituted of, for example, a pressure container made of stainless steel and having an inner wall coated with Teflon (registered trademark), and comprises a square tubular case body 10a having an opening in its upper portion, and a lid body 10b provided in the case body 10a to open and close the opening. The reaction tank 10 is constituted to store the plating solution 36 and supercritical CO₂. The reaction tank 10 has an internal space in which the plating solution 36 and supercritical CO₂ are stored and the anode 11 is disposed to face the cathode 12. The reaction tank 10 is coupled to the plating solution supply section 17 and the supercritical fluid supply section 18 via the fluid supply pipe 38 and the liquid supply pipe 34, and is also coupled to the treatment container 19 via the discharge pipe 47.

The anode 11 shown in FIG. 2 and FIG. 3 is a porous anode plate 21. The anode plate 21 is constituted of a base 21a that is, for example, a pure Pt plate or a metal layer made of a metal material of Ti or the like and having the surface coated with an Ir film, an Ir and Pt laminated film, or the like. For example, the anode plate 21 is constituted as a meshed plate having a predetermined thickness and having a large number of passages 21c that are through holes passing through the plate in a thickness direction. For example, an arrangement pitch of the passages 21c is set to be smaller than a minimum width of a pattern of the resist mask 15. Specifically, when the minimum width of the pattern of the resist mask is 10 μm, the arrangement pitch of the passages 21c is adjusted in a range of about 1 to 10 μm. Therefore, a first region A1 of the resist mask 15 which corresponds to a film forming region and in which any resist is not formed on a cathode plate 31 side of the anode plate 21 communicates with a second region A2 on a side opposite to the first region via the anode plate 21, through the passages 21c. Therefore, the plating solution 36 passing through the passages 21c can flow from the second region A2 on one side of the anode plate 21 into the first region A1 on the other side thereof.

Here, a height variation of the plated film to be formed changes in accordance with a thickness l of the resist mask, a height d of the plated film, an arrangement pitch p of the passages 21c, and a diameter w of each passage 21c. In the present embodiment, a relation between a plating current distribution and each of these values is clarified, and ranges of the values l, d, p and w which are capable of suppressing the height variation of the plated film to be formed are clarified. Spread of the current distribution decreases in accordance with increase of a distance (l-d) between the anode plate 21 and the plated film 52. Furthermore, the spread of the current distribution decreases in accordance with decrease of the arrangement pitch p of the passages 21c. Furthermore, the spread of the current distribution decreases in accordance with increase of the diameter w of the passage 21c. It is preferable that the above relations are generally taken into consideration, and relations among the thickness l of the resist mask, the height d of the plated film, the arrangement pitch p of the passages 21c and the diameter w of the passage 21c are adjusted so that l-d>4 μm, and p<4 μm, and w>1 μm to suppress the height variation of the plated film down to ±10% or less when the minimum width of the pattern of the resist mask is 10 μm.

The anode plate 21 is supported by the anode supporter 13 by bonding or the like, and attached thereto movably in a Z-axis direction. The anode plate 21 is coupled to a cathode side of the direct constant current source 16 via a coupling lead. The resist mask 15 is disposed on the cathode plate 31 side of the anode plate 21.

The resist mask 15 is a film made of an insulating material and is constituted of, for example, an organic film containing polyimide, epoxy or the like as a main component. The resist mask 15 is formed in a predetermined pattern shape corresponding to a pattern shape of the plated film 52 to be formed. The pattern shape of the resist mask 15 is, for example, an inverted pattern shape having the same center line as in a pattern of the plated film 52 to be formed on the cathode plate 31 and having an adjusted pattern width.

For example, in case of forming the plated film 52 in a wire pattern having a width of about 20 μm, a height, i.e., a film thickness of about 10 μm, a half-value width of 10 μm to a maximum height in a pattern cross section, and a pitch of 40 μm, the resist mask 15 is formed in a pattern state having a minimum pattern width of 10 μm, a space of 30 μm and a pitch of 40 μm.

In the region A1 where the resist mask 15 is not formed, the anode plate 21 is exposed to the cathode plate 31, and the plated film 52 is formed on the cathode plate 31 at a position facing the exposed region of the anode plate 21.

The anode supporter 13 is an adjusting device constituted to adjust a height (Z-axis direction) position of the anode, so that, for example, a distance L2 between the resist mask 15 constituted integrally with the anode 11 and the cathode is adjustable. The anode supporter 13 comprises a piezoelectric section 13a constituted so that its length in the Z-axis direction is variable, a first support plate 13b disposed on one side of the piezoelectric section 13a and having a bonding surface bonded to the lid body 10b, and a second support plate 13c disposed on the other side of the piezoelectric section 13a and having a support surface bonded to the anode plate 21.

The piezoelectric section 13a comprises, for example, layers of a piezoelectric ceramic material, and has voltage terminals 13d for electric coupling. The length of the piezoelectric section 13a which is vertical to the surface of the cathode plate 31 in the Z-axis direction is variable at an accuracy of, for example, 0.1 μm or less in a range of 0 to 40 μm in accordance with a voltage to be applied to the voltage terminals 13d.

One end face of the anode supporter 13 is bonded to a lower surface of the lid body 10b of the reaction tank 10, and the other end face thereof is bonded to the anode plate 21. The length of the piezoelectric section 13a of the anode supporter 13 in the Z-axis direction is adjusted in accordance with the applied voltage, to adjust a position of the anode plate 21 in the Z-axis direction, so that the distance L2 between the surface of the resist mask 15 and the surface of the cathode plate 31 in the Z-axis direction is adjusted. It is to be noted that the distance L2 may be set to 0 to bring the resist mask 15 into contact with the cathode plate 31, and in this case, the adjusting device comprising the piezoelectric section 13a and the voltage terminals 13d is not necessarily required.

The cathode 12 is the cathode plate 31 comprising a wafer 31a and a seed layer 31b formed on the wafer 31a. On the wafer 31a made of Si in the cathode 12, for example, a Ti/Cu laminated film is formed as the seed layer 31b by a physical depositing method such as a sputtering or evaporating method. For example, in the present embodiment, the disc-like cathode plate 31 having a size of φ200 mm is used. The cathode plate 31 is coupled to an anode side of the direct constant current source 16 via a coupling lead.

It is to be noted that a Ti layer is formed to increase a close contact strength with the Si wafer 31a, and it is preferable that a film thickness of the layer is about 0.1 μm. A Cu layer is formed to contribute mainly to power supply, and it is preferable that a film thickness of the layer is 0.2 μm or more.

The cathode supporter 14 comprises a support base 14a disposed in the case body 10a to support the cathode plate 31 on its upper surface, and a pressing member 14b fixing the cathode plate 31 to the support base 14a.

The plating solution supply section 17 comprises a plating solution tank 33 storing the plating solution 36 excluding CO₂ and coupled to the reaction tank 10 via the liquid supply pipe 34. The liquid supply pipe 34 constitutes a flow channel extending from the plating solution tank 33 into the reaction tank 10. The liquid supply pipe 34 includes a control valve 35 that adjusts a flow rate of a fluid flowing through the pipe.

The plating solution 36 is, for example, the fluid including metal ions and an electrolyte. As the plating solution 36, for example, a usual copper sulfate plating solution is usable. In the present embodiment, as the plating solution 36, there is used the usual copper sulfate plating solution obtained by adding a surfactant to a mixed solution of copper (II) sulfate pentahydrate and sulfuric acid. It is to be noted that the plating solution 36 is not limited to this example, and there may be used another plating solution such as a copper pyrophosphate plating solution or a copper sulfamate plating solution.

The supercritical fluid supply section 18 comprises a carbon dioxide cylinder 37, and a temperature adjusting pump 39 communicating with the carbon dioxide cylinder 37 and the reaction tank 10 via the fluid supply pipe 38.

It is known that a supercritical fluid does not belong to a solid, a liquid or a gas in a state diagram of a substance which is determined by a temperature and a pressure, and contributes to nano-level permeability and fast reaction because the fluid has characteristics such as high diffusibility, high density and zero surface tension. In the present embodiment, supercritical CO₂ is used as the supercritical fluid. It is to be noted that in the present embodiment, there is used supercritical CO₂ emulsion (SCE) emulsified by adding a surfactant to carbon dioxide so that the fluid is applicable to electroplating.

The carbon dioxide cylinder 37 is a container storing high-pressure carbon dioxide. The carbon dioxide cylinder 37 stores, for example, liquefied CO₂ of 4N.

The temperature adjusting pump 39 comprises a heater 41 coupled to the carbon dioxide cylinder 37 via the fluid supply pipe 38 to heat a carbon dioxide gas from the carbon dioxide cylinder 37, a compressor 42 of a pressurizing device that compresses the carbon dioxide gas, and a pressure gauge 43 coupled to an outlet side of the compressor 42.

The heater 41 heats carbon dioxide at a predetermined temperature that is not lower than its critical temperature of 31.1° C., for example, at 40° C. in the present embodiment. The compressor 42 is, for example, a high-pressure pump, and pressurizes the carbon dioxide gas at a predetermined pressure that is not less than an atmospheric pressure and is not less than its critical pressure of 7.38 MPa, for example, at 15 MPa in the present embodiment.

The fluid supply pipe 38 constitutes a flow channel passing from the carbon dioxide cylinder 37 through the temperature adjusting pump 39 into the reaction tank 10. On an upstream side and a downstream side of the temperature adjusting pump 39 along the fluid supply pipe 38, control valves 44 and 45 are provided to adjust the flow rate of the fluid flowing in the pipe.

The supercritical fluid supply section 18 supplies carbon dioxide having the flow rate determined by the control valve 44, from the carbon dioxide cylinder 37 to the heater 41, and the heater 41 heats carbon dioxide at a temperature that is not lower than a critical point of 31° C. Then, carbon dioxide is pressurized at a pressure that is not less than a critical point of 7.4 MPa by the compressor 42, and carbon dioxide brought into a supercritical state is supplied to the reaction tank 10.

The direct constant current source 16 of a power source is a current supply device that energizes between the anode 11 and the cathode 12 to reduce and deposit, on the cathode 12, the metal ions in the plating solution 36. A cathode of the device is coupled to a pattern polar surface 22 via the anode plate 21 of the anode 11, and an anode thereof is coupled to the seed layer 31b of the cathode plate 31.

The treatment container 19 is, for example, a container made of a metal, and is coupled to the reaction tank 10 via the discharge pipe 47. The discharge pipe 47 constitutes a flow channel extending from the reaction tank 10 to the treatment container 19. The discharge pipe 47 comprises a branch pipe 48 constituting a branch flow channel branching from the middle of a discharge flow channel and returning to the discharge flow channel again. On an upstream side from a branch portion of the discharge pipe 47, a control valve 49 is provided to adjust the flow rate of the fluid flowing in the pipe. A back pressure adjusting valve 46 is provided in the branch flow channel. The back pressure adjusting valve 46 is constituted of a variable valve that is capable of accurately controlling the flow rate of the fluid, and has a function of keeping the pressure in the reaction tank 10 at a predetermined pressure of 15 MPa.

An electroplating method of forming a pattern in the cathode plate 31 by use of the electroplating apparatus 1 constituted as described above will be described with reference to FIG. 1 and FIG. 5.

The electroplating method according to the present embodiment comprises arranging the anode 11 and the cathode 12 in the reaction tank 10 and interposing the resist mask 15 between the anode and the cathode so that the anode faces the cathode via the resist mask, disposing the plating solution 36 in the reaction tank 10, and setting a potential of the cathode plate 31 to a negative potential to form the plated film 52 of the metal film on the surface of the cathode plate 31.

Specifically, the cathode plate 31 is initially immersed into an electrolyte solution in a pretreatment. In the present embodiment, the cathode plate is immersed into 10 wt. % of H₂SO₄ aqueous solution for one minute to remove a natural oxide film formed on the Cu surface of the seed layer 31b. It is to be noted that it is preferable to suitably adjust a type or composition of a pretreatment liquid and treatment time in accordance with a growth state of the oxide film so that the oxide film can securely be removed.

Then, the pretreated cathode plate 31 is disposed to face the anode plate 21 via the resist mask 15 in the reaction tank 10. The cathode plate 31 and the anode plate 21 are arranged in this manner, and then the lid body 10b of the reaction tank 10 is closed to hermetically close the reaction tank 10.

The control section 20 varies the length of the anode supporter 13 in the Z-axis direction to adjust a position of the anode 11 in the Z-axis direction, and controls the distance L2 between the resist mask 15 and the cathode plate 31 while maintaining a state where the surface of the resist mask 15 is parallel to the surface of the cathode plate 31, to set a distance L2′ between the surface of the plated film formed on the surface of the cathode and the resist mask 15 to, for example, a predetermined value smaller than 1 μm.

The distance L2=L2′ prior to the plating is set by, for example, electrostatic field simulation. It is to be noted that in the present embodiment, the passages 21c are formed in the anode plate 21, and hence the plating solution 36 can flow from the backside of the anode plate 21 into the surface of the anode plate which faces the cathode plate 31. Therefore, it is not necessary to acquire the large distance L2 for the supply of the plating solution 36. Consequently, the distance L2 can be set to 0 or a value close to 0. For example, in the present embodiment, the distance L2=L2′ prior to the plating is set to 1 μm or less.

Next, the plating solution 36 and CO₂ in the supercritical state are introduced into the reaction tank 10. Specifically, the control section 20 initially opens the control valve 35 of the liquid supply pipe 34 as much as a predetermined amount, to supply the plating solution 36 from the plating solution tank to the reaction tank 10 at the predetermined flow rate determined by the control valve 35.

At this time, the plating solution 36 disposed in the reaction tank 10 passes through the passages 21c to flow from the upside of the anode plate 21 into the first region A1 where the resist mask 15 is not disposed between the anode plate 21 and the cathode plate 31.

Next, the control section 20 opens the control valves 44 and 45 of the fluid supply pipe 38 as much as predetermined amounts, to supply carbon dioxide from the carbon dioxide cylinder 37 to the temperature adjusting pump 39 at the flow rate determined by the control valve 44. Then, the control section 20 controls the heater 41 to heat carbon dioxide at its critical temperature of 31.1° C. or more, and controls the compressor 42 to pressurize the carbon dioxide gas at the predetermined pressure, for example, at the critical pressure of 7.38 MPa or more. Furthermore, the control section controls the compressor 42 and the back pressure adjusting valve 46 which are coupled to the reaction tank 10, and adjusts the inside of the reaction tank 10 to 15 MPa. Furthermore, the control section executes control to also adjust the temperature of the outside of the reaction tank 10 to 40° C. by an external heater provided on the outside of the reaction tank 10.

Here, the flow rate is set so that a volume ratio of the plating solution 36 to the supercritical fluid of CO₂ is, for example, 8:2, i.e., so that CO₂ has a ratio of 20 vol. %. In general, CO₂ comes into the supercritical state at supercritical points of 31° C. and 7.4 MPa, but in the present embodiment, there are provided a margin of +9° C. to the critical temperature and a margin of +7.6 MPa to the critical pressure so that all CO₂ in the reaction tank 10 is surely in the supercritical state. However, these values can suitably be determined in consideration of the temperature, pressure distribution or the like in the reaction tank 10.

The control section 20 energizes the direct constant current source 16 with a plating current of a constant current for predetermined time, when the pressure and temperature in the reaction tank 10 which are detected by the pressure gauge 43 and a thermometer are stabilized at predetermined values or more.

When the cathode plate 31 turns to the anode in the reaction tank 10 by the energization, an electric field on the surface of the cathode plate 31 is concentrated on a portion of the resist mask 15 which faces a pattern of a region where the anode plate 21 is exposed, because the distance L2 is short. Consequently, on the surface of the cathode plate 31 of the cathode, the plated film 52 is formed in a pattern state corresponding to the pattern in which the resist mask 15 is not disposed and the anode plate 21 is exposed, and the Cu wire is formed.

Here, a theory of electrostatic field is applied as it is to the electric field to be formed on the cathode surface, and the electric field is obtainable by solving Laplace's differential equation under appropriate boundary conditions. To be exact, the plating current distribution is modified in accordance with a current density during plating and characteristics of the plating solution 36. The current distribution obtainable by the Laplace's differential equation is usually called a primary current distribution. In case of the plating that causes a chemical reaction on electrode surfaces, polarizations are generated in the anode and the cathode, respectively, and hence it is necessary to take this phenomenon as the boundary condition. The current distribution obtainable from this result is called a secondary current distribution, and the secondary current distribution has more tendency to uniformity than the primary current distribution.

An index of the uniformity of the secondary current distribution is determined by a product W of conductivity of the plating solution 36 and polarization resistance thereof. When the product W is 0, the secondary current distribution becomes equal to the primary current distribution, and as the product W increases, the secondary current distribution is more uniformized than the primary current distribution.

In other words, a constant relation occurs between the primary current distribution and the secondary current distribution. For example, when the above product w is 0.5 to a standard deviation σ of the primary current distribution, the standard deviation of the secondary current distribution is approximately ⅔ of the standard deviation σ, and when the product W is 1.0, the standard deviation of the secondary current distribution is approximately ½ of the standard deviation σ.

It is to be noted that in the usual electroplating, as temperature of the plating solution 36 rises, the conductivity tends to increase, and the polarization resistance tends to decrease. Detailed behaviors of these tendencies vary with the plating solution 36 for use. Therefore, in the usual plating in which a uniform plated film thickness is required, there are selected conditions to stably increase the index of the product of the conductivity of the plating solution 36 and the polarization resistance thereof. Furthermore, potential-to-current characteristics of the cathode surface, i.e., a cathode polarization line is not usually linear, but the characteristics are close to those of a secondary curve. Consequently, the current density increases, and the polarization resistance tends to decrease. Therefore, in the usual plating, it is preferable to decrease the current density to such an extent that the film is formable within plating time allowed in consideration of productivity. In the Cu plating by the plating solution 36 made of copper sulfate and sulfuric acid and called a highly uniform electrodeposition bath in which concentration of sulfuric acid is high or a low copper concentration bath, the conditions on which the product W is usually 0.5 or more are mainly for use.

On the other hand, in the electroplating method according to the present embodiment, it is preferable that the product W is smaller than 0.5 to obtain the patterned plated film 52 corresponding to a patterned electrode.

In other words, according to the usual Cu plating, for the purpose of improving the uniformity of the current density on the surface of the cathode plate 31, the current density is usually set to 5 A/dm² or less so that the polarization resistance increases. However, in the present embodiment, for the purpose of decreasing the polarization resistance, the current density is set to 10 A/dm² that is little higher than the current density of the usual Cu plating. An average film formation rate at this time is about 2 μm/min.

In the present embodiment, the control section 20 adjusts and increases the distance L2 in accordance with film formation time, current quantity or the thickness of the plated film 52 to be formed.

The control section 20 applies the voltage to the voltage terminals 13d with an elapse of time immediately after the start of the plating, to execute control so that the length of the piezoelectric section 13a in the Z-axis direction contracts at the same rate as the average film formation rate of the plated film 52, for example, at 2 μm/min here. In other words, it is considered that when the distance L2 is small, the distance L2′ between the plated film 52 formed on the seed layer 31b and the resist mask 15 contracts depending on a degree of film formation, the plated film comes in contact with or comes excessively close to the resist mask, and hence a film formation treatment is obstructed. In the present embodiment, however, the distance L2 in the Z-axis direction increases at the rate equivalent to the film formation rate, whereby the distance L2′ between the surface of the plated film 52 of a film forming surface and the resist mask 15 can be maintained at a constant value, for example, a value equivalent to the distance L2 at the start of the film formation.

Then, after the elapse of predetermined time from the start of the plating, the power source of the direct constant current source 16 is turned off to stop the energization, and the control of the length of the anode supporter 13 in the Z-axis direction is also stopped. For example, time from the start of the energization to the stop thereof is set to 5 min.

Afterward, the control valve 49 on the discharge side is opened to discharge the supercritical fluid or the plating solution 36 from the reaction tank 10, and the inside of the reaction tank 10 is returned to ordinary pressure. Then, the lid body 10b of the reaction tank 10 is opened to take out the cathode plate 31 on which a Cu covering film is formed, followed by water washing and drying.

Subsequently, the cathode plate 31 on which the plated film 52 is formed is immersed into a mixed aqueous solution of 10 wt. % of H₂SO₄ and 10 wt. % of H₂O₂, and etch-back is performed to remove excessive Cu deposited between the wire patterns formed by the Cu plating and a Cu layer constituting the seed layer 31b.

It is to be noted that the plated Cu film is dissolved in the present step, but its dissolution thickness is about 2 μm, and hence there is not any hindrance. Cu residue between the wire patterns is removed, and then the Ti layer of the seed layer 31b is exposed, and hence etching of Ti is continuously performed. The etching of Ti is performed with a mixed solution of H₂O₂, ammonia water and a chelating agent. Furthermore, during the Ti dissolution, the plated Cu film is hardly dissolved.

In the above step, the wire pattern is formable as the plated film 52 in a desirable region on the cathode plate 31 by the Cu plating, and the semiconductor device 100A is manufactured.

It is to be noted that the semiconductor device 100A shown in FIG. 5 comprises semiconductor elements 101, a wire 31g coupled to each semiconductor element 101, an insulating layer 31f, and the plated film 52 coupled to the wire 31g.

Furthermore, the cathode in which any semiconductor elements are not formed is used as the cathode plate 31, and the wire pattern is formed in the cathode plate 31 by the electroplating apparatus 1 and the electroplating method mentioned above, whereby the wire substrate can be manufactured. In other words, a manufacturing method of the wire substrate according to the present embodiment comprises forming a film of the wire as the plated film 52 on the cathode plate 31 by the electroplating apparatus 1 and the electroplating method mentioned above.

As to the Cu wire formed as described above, a surface shape measurement of the wire is performed with a laser microscope. After the plating, the wire having a half-value width of about 10 μm can be formed while a peak value of the plated film thickness is 12 μm, and after the etching, there can be formed the Cu wire having a half-value width of about 8 μm to a film thickness peak value of 10 μm, a wire width of about 20 μm, a wire height of about 10 μm and an aspect ratio of 0.5 or more.

According to the electroplating apparatus 1 and the electroplating method of the present embodiment, the following effects are obtainable. In other words, the anode plate 21 having the passages 21c is disposed to face the cathode plate 31 via the resist mask 15 in which the pattern is formed, so that the plated film can accurately be formed. Specifically, the fine wire having a high aspect can be achieved by use of a solid material, and hence as compared with a printing method using paste and an ink jet method, it is possible to obtain the effects that the wire has a low resistance and is therefore excellent in electric characteristics and that the wire has a high ductility and a high tensile strength and is therefore excellent in mechanical characteristics. Furthermore, according to the electroplating apparatus 1 and the electroplating method of the above present embodiment, it is not necessary to form a resist film on the wafer every time the plated film is formed, and hence steps concerned with the resist, e.g., steps of resist formation, exposure, development and peel steps can be omitted. In consequence, the treatment steps can noticeably be decreased.

According to the electroplating apparatus 1 and the electroplating method of the present embodiment, the passages 21c through which the plating solution can flow are formed in the anode plate 21, and hence it is possible to effectively supply the plating solution 36 from the backside of the anode plate 21 to the space between the cathode plate 31 and the resist mask 15. Therefore, it is possible to decrease the distance L2 between the cathode plate 31 and the resist mask 15, and the distance can be set to, for example, 0. Here, in the pattern shape of the plated film 52 to be formed, as the distance between the surface on which the pattern is formed and the resist mask 15 in the form of the pattern decreases, the accuracy of the film formation further improves. In other words, according to the present embodiment, it is possible to decrease the distance between the resist mask 15 and the cathode plate 31, and hence more accurate pattern formation is enabled.

FIG. 4 shows the secondary current distribution in the surface of the cathode which is obtained by the electrostatic field simulation. FIG. 4 shows the secondary current distribution in the surface of the cathode, when the porous anode plate 21 is used to form the anode pattern having a width of 5 μm and the distance L2 between the resist mask 15 and the cathode plate 31 is set to 1 μm. Furthermore, FIG. 4 shows a secondary current distribution in the surface of the cathode as a comparative example, when an anode plate of a plate shape in which pore portions are not formed is used to form an anode pattern having a width of 5 μm and the distance L2 is set to 5 μm.

It is seen from FIG. 4 that in the present embodiment where the passages 21c are formed in the anode plate 21 to decrease the distance L2, as compared with the comparative example where any passages are not formed and the distance L2 is large, the half-value width to the wire height of the cross section of the wire pattern decreases as much as about 40%. Therefore, according to the electroplating method of the present embodiment, more accurate pattern can be achieved.

Furthermore, according to the electroplating apparatus 1 and the electroplating method of the present embodiment, supercritical CO₂ is introduced into the reaction tank 10, whereby the accurate pattern formation is enabled even when the distance L2 is small. In other words, it is considered that when the distance L2 is small, ions are hardly supplied, but supercritical CO₂ micelles in the plating solution 36 having the high permeability enter a space between electrodes, and hence the plating solution 36 around the micelles also flows. Consequently, it is possible to promote the supply of the plated ions between the electrodes.

Furthermore, according to the electroplating apparatus 1 and the electroplating method of the above present embodiment, the distance L2 is adjusted in accordance with the thickness of the film to be formed. Therefore, also when the distance L2 is small, it is possible to acquire a space between the plated film 52 and the anode as much as a predetermined value or more, and hence the present invention is also applicable to the formation of the plated film 52 having a large thickness.

### Second Embodiment

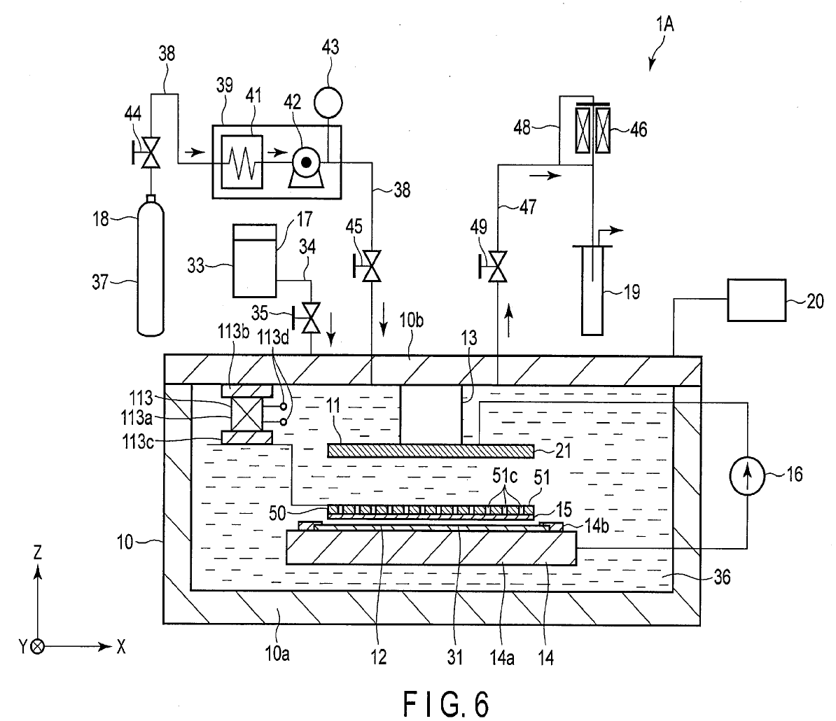

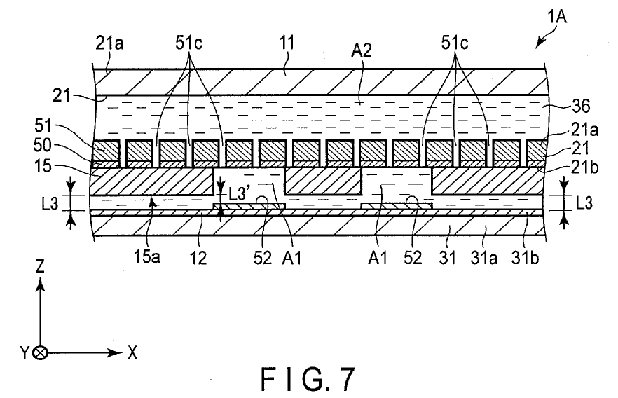

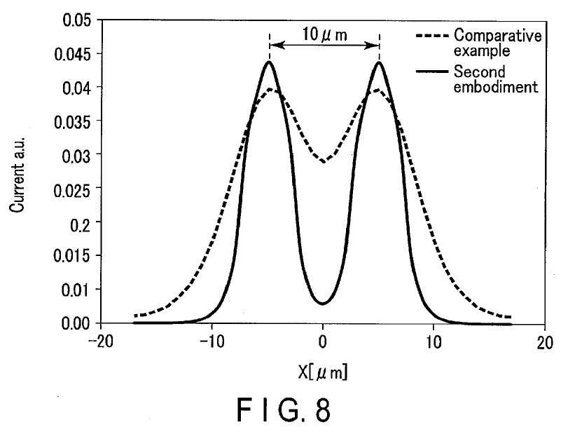

Hereinafter, an electroplating apparatus 1A, an electroplating method and a manufacturing method of a wire substrate according to a second embodiment of the present invention will be described with reference to FIG. 6 to FIG. 8. FIG. 6 is an explanatory view showing a constitution of the electroplating apparatus 1A according to the second embodiment, FIG. 7 is an explanatory view showing a schematic constitution of a part of the electroplating apparatus 1A, and FIG. 8 is an explanatory view showing a current distribution in a cathode of the electroplating apparatus 1A.

As shown in FIG. 6 to FIG. 8, according to the electroplating apparatus, the electroplating method, a manufacturing method of a semiconductor device and the manufacturing method of the wire substrate of the second embodiment, a passage 15a is formed in a resist mask 15, and an anode plate 21 is disposed away from the resist mask 15. Furthermore, in the present embodiment, the anode plate 21 is fixed, and the resist mask 15 is movably supported. Additionally, in the electroplating apparatus 1A, the electroplating method, the manufacturing method of the semiconductor device and the manufacturing method of the wire substrate, constitutions of respective components of the apparatus and details of the electroplating method are similar to those in the electroplating apparatus 1, the electroplating method, the manufacturing method of the semiconductor device and the manufacturing method of the wire substrate according to the above first embodiment. Therefore, descriptions of common constitutions and methods are omitted.

The electroplating apparatus 1A according to the present embodiment comprises a reaction tank 10 of a reaction section storing a plating solution 36, an anode 11 disposed in the reaction tank 10, a cathode 12 disposed to face the anode 11, a anode supporter 13 supporting the anode 11, a cathode supporter 14 supporting the cathode 12, a mask member 50 comprising the resist mask 15 interposed between the anode 11 and the cathode 12, an adjusting device 113 that moves the resist mask 15 of the mask member 50, a direct constant current source 16 for energization, a supercritical fluid supply section 18 coupled to a supply side of the reaction tank 10 via a fluid supply pipe 38, a plating solution supply section 17 coupled to the supply side of the reaction tank 10 via a liquid supply pipe 34, a treatment container 19 coupled to a discharge side of the reaction tank 10 via a discharge pipe 47, and a control section 20 that controls the respective components. The mask member 50 comprises a porous support layer 51 of a supporter and the resist mask 15 of a film formed in a predetermined pattern on the surface of the support layer 51, which are laminated.

The support layer 51 is made of an insulating material such as polyimide and formed in a meshed layer so that the plating solution 36 can flow through the layer. Alternatively, the support layer may be formed by forming through holes in an inorganic material of Si or the like having a certain thickness. For example, the support layer 51 has a predetermined thickness and is constituted of a meshed later having a large number of passages 51c which are through holes extending through the layer in a thickness direction. The passages 51c are constituted so that the plating solution 36 can flow from one surface side of the support layer 51 into the other surface side thereof. The support layer 51 performs a function of the supporter to support the resist mask 15 at a predetermined position. For example, an arrangement pitch of the passages 51c of the support layer 51 is set to be smaller than a minimum opening width of the pattern of the resist mask 15. Therefore, a first region A1 where any resist of the resist mask 15 is not formed on a cathode plate 31 side of the mask member 50 communicates with a second region A2 on a side opposite to the first region via the mask member 50 between the mask member and the anode plate 21, via the passages 51c. The support layer is constituted so that the plating solution 36 passing through the passages 51c can flow from the second region A2 on one side of the mask member 50 into the first region A1 on the other side thereof.

Here, a height variation of a plated film to be formed changes in accordance with a thickness l of the resist mask, a height d of the plated film, an arrangement pitch p of the passages 51c, and a diameter w of each passage 51c. In the present embodiment, a relation between a plating current distribution and each of these values is clarified, and ranges of the values l, d, p and w which are capable of suppressing the height variation of the plated film to be formed are clarified. Spread of the current distribution decreases in accordance with increase of a distance (l-d) between the anode plate 21 and a plated film 52. Furthermore, the spread of the current distribution decreases in accordance with decrease of the arrangement pitch p of the passages 51c. Furthermore, the spread of the current distribution decreases in accordance with increase of the diameter w of the passage 51c. It is preferable that the above relations are generally taken into consideration, and relations among the thickness l of the resist mask, the height d of the plated film, the arrangement pitch p of the passages 51c and the diameter w of the passage 51c are adjusted so that l-d>4 μm, and p<4 μm, and w>1 μm to suppress the height variation of the plated film down to ±10% or less when a minimum width of the pattern of the resist mask is 10 μm.

The resist mask 15 is a film made of an insulating material and is constituted of, for example, an inorganic film made of SiO₂, SiN or the like or an organic film made of polyimide, epoxy or the like. The resist mask 15 is formed in a predetermined pattern shape corresponding to a pattern shape of the plated film 52 to be formed. The pattern shape of the resist mask 15 is, for example, an inverted pattern shape having the same center line as in a pattern of the plated film 52 to be formed on the cathode plate 31 and having an adjusted pattern width.

In the region A1 of the mask member 50 where the film of the resist mask 15 is not formed, the anode plate 21 is disposed to face the cathode plate 31, and at a position facing the anode plate 21, the plated film 52 is formed on the cathode plate 31. It is to be noted that in the present embodiment, the anode plate 21 has the plate shape in which any through holes constituting passages 21c are not formed.

The adjusting device 113 adjusts the position of the resist mask 15 in a Z-axis direction, so that, for example, a distance L3 between the resist mask 15 and the cathode is adjustable. The adjusting device 113 is constituted similarly to the anode supporter 13, and comprises a piezoelectric section 113a constituted so that its length in the Z-axis direction is variable, a first support plate 113b disposed on one side of the piezoelectric section 113a and having a bonding surface bonded to a lid body 10b, and a second support plate 113c disposed on the other side of the piezoelectric section 113a and having a support surface bonded to the resist mask 15.

The piezoelectric section 113a comprises, for example, layers of a piezoelectric ceramic material, and has voltage terminals 113d for electric coupling. The length of the piezoelectric section 113a which is vertical to the surface of the cathode plate 31 in the Z-axis direction is variable at an accuracy of, for example, 0.1 μm or less in a range of 0 to 40 μm in accordance with a voltage to be applied to the voltage terminals 113d.

In the present embodiment, the distance L3 between the resist mask 15 and the cathode plate 31 is set to 1 μm or less. On the other hand, the anode plate 21 is disposed away from the mask member 50 having the resist mask 15, and the plating solution 36 is stored in a space between the anode plate 21 and the mask member 50.

The electroplating method according to the present embodiment comprises arranging the anode 11 and the cathode 12 in the reaction tank 10 in which the plating solution 36 is stored and interposing the mask member 50 having the resist mask 15 so that the anode faces the cathode via the mask member; and setting a potential of the cathode 12 to a negative potential to the anode, to form the plated film 52 made of a metal on the surface of the cathode 12.

Specifically, similarly to the above first embodiment, the control section 20 initially arranges the cathode plate 31 and the anode plate 21 which are subjected to a pretreatment away from each other as much as a predetermined distance so that the cathode plate faces the anode plate via the mask member 50, and supplies the plating solution 36 and supercritical CO₂ to the reaction tank 10. Afterward, the control section 20 forms the plated film 52 on the cathode plate 31 by the energization. It is to be noted that during the film formation, the control section controls the adjusting device to increase the distance L3 in accordance with a proceeding degree of the film formation, for example, a current quantity, elapsed time or a thickness of the formed film, or the like in the same manner as in the electroplating method according to the first embodiment.

The present embodiment also produces effects similar to those of the above first embodiment. The passages 51c through which the plating solution can flow are formed in the support layer 51, and hence it is possible to effectively supply the plating solution 36 from the backside of the support layer 51 to the space between the cathode plate 31 and the resist mask 15. Therefore, it is possible to decrease the distance L3 between the cathode plate 31 and the resist mask 15, and the distance can be set to, for example, 0. Here, in the pattern shape of the plated film 52 to be formed, as the distance between the surface on which the pattern is formed and the resist mask 15 in the form of the pattern decreases, the accuracy of the film formation further improves. In other words, according to the present embodiment, it is possible to decrease the distance between the resist mask 15 and the cathode plate 31, and hence more accurate pattern formation is enabled.

Furthermore, the distance L3 between the resist mask 15 and the cathode 12 is controlled, to set a distance L3′ between the resist mask 15 and the surface of the plated film formed on the surface of the cathode 12 to 1 μm or less, so that a wire pattern can accurately be formed on the cathode 12. Consequently, a step of forming a film of a resist layer on the surface of the cathode 12 every time can be omitted.

It is to be noted that the present invention is not limited to the above embodiments as it is, and in an implementing stage, constituent elements can be modified and embodied without departing from the gist of the invention.

It is to be noted that the present invention is not limited to the above embodiments. For example, in an electroplating method according to another embodiment, an anode 11 and a resist mask 15 are formed in a part of a cathode 12, and in this constitution, a film formation treatment and a moving treatment may be repeated to perform pattern formation in batches. Specifically, there are repeated plural times the film formation treatment of forming a plated film 52 of a pattern corresponding to a pattern shape of the anode 11 in a part of the surface of the cathode and the moving treatment of moving the cathode and the anode relatively on an XY-plane, to form a desirable pattern shape constituted of parallel unit patterns on the surface of the cathode.

Specifically, the treatment of forming the film having a predetermined thickness is performed in the same manner as in the above first embodiment, a position of the anode 11 is shifted in a predetermined direction as much as a dimension of the anode 11, and then a distance L2 is returned to an initial value. Then, a current is applied again, to form the film in a pattern state corresponding to that of the anode 11. This film formation treatment and the moving are repeated to perform the pattern formation of a broad range in batches. In other words, a partial film formation treatment is repeated plural times while shifting the position as much as a predetermined pitch, to perform the film formation treatments in divided regions. Consequently, a Cu wire pattern is formed in all the regions on a seed layer 31b of a cathode plate 31.

Afterward, in the same manner as in the first embodiment, the inside of a reaction tank 10 is returned to ordinary pressure to perform a discharge treatment, and the cathode plate 31 on which a Cu covering film is formed is taken outside, followed by a water washing and drying treatment, to perform an etch-back treatment.

The present embodiment also produces effects similar to those of the above first and second embodiments. Furthermore, according to the present embodiment, simplification of the pattern of the anode as well as decrease of an area of the anode can be achieved, and hence it is also possible to obtain effects that time and cost required for design or manufacturing of the anode can be decreased.

Furthermore, the plating solution 36 and the supercritical fluid are not limited to the above-mentioned examples, and the plating solution 36 of Ni or the like and the supercritical fluid of H₂O or the like are also usable. Furthermore, when the plating solution can flow through a narrow region between the anode 11 and the cathode 12 by the above-mentioned method, the supercritical fluid does not necessarily have to be mixed with the plating solution. It is to be noted that a Ti/Pt laminated film is a so-called insoluble anode, but the film may include Ir in place of Pt, or a soluble anode of pure Cu, P-containing Cu or the like is also usable. There has been described the example where the anode plate 21 and the support layer 51 have the meshed structure, but the present invention is not limited to this example. For example, the anode plate and the support layer may have another configuration, for example, a porous configuration having a large number of pores.

In the above embodiment, as the adjusting device that adjusts the position in the Z-axis direction, a piezo type adjusting device comprising piezoelectric elements has been illustrated, but the present invention is not limited to this example, and any type of mechanism such as a mechanical type using a rotary motor and a gear, a voice coil type or linear motor type may be used. Furthermore, in the above embodiment, the constitution that moves the anode 11 has been illustrated, but the present invention is not limited to this example. For example, as a still further embodiment, a constitution that moves the cathode 12 or a constitution that moves both the anode 11 and the cathode 12 is also applicable.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. An electroplating method comprising:
arranging an anode having passages through which a plating solution flows and a cathode to face each other via a resist mask, in a reaction section storing the plating solution; and
setting a potential of the cathode to a negative potential to the anode, to form a metal plated film on the surface of the cathode.

2. An electroplating method comprising:
arranging an anode and a cathode to face each other, via a mask member comprising a resist mask and a support layer having passages through which a plating solution flows, in a reaction section storing the plating solution; and
setting a potential of the cathode to a negative potential to the anode, to form a metal plated film on the surface of the cathode.

3. The electroplating method according to claim 1,
wherein the anode is constituted in the foam of a porous plate having through holes making up the passages, and
a distance between the resist mask and the cathode during the formation of the plated film is 1 pm or less.

4. The electroplating method according to claim 2,
wherein the anode is made of a metal material,
the support layer is constituted in the form of a porous plate having through holes making up the passages,
the resist mask has a pattern corresponding to a pattern shape of the plated film to be formed, and
a distance between the resist mask and the cathode during the formation of the plated film is 1 μm or less.

5. The electroplating method according to claim 1,
wherein the passages have through holes arranged at a pitch smaller than a minimum opening width of a pattern of the resist mask.

6. The electroplating method according to claim 1,
wherein a difference between a thickness of the resist mask and a thickness of the plated film to be finally formed is larger than 4 μm, a pitch of the through holes is smaller than 4 μm, and a diameter of each through hole is larger than 1 μm.

7. The electroplating method according to claim 1,
wherein the plating solution contains metal ions to be plated, an electrolyte and a surfactant.

8. The electroplating method according to claim 1,
wherein the anode is an anode plate having a metal layer,
the cathode is a cathode plate having a wafer and a seed layer formed on the surface of the wafer, and
the resist mask is disposed on the surface of the anode plate on a cathode plate side.

9. The electroplating method according to claim 1, further comprising:
pressurizing the reaction section at an atmospheric pressure or more.

10. The electroplating method according to claim 1, further comprising:
putting a supercritical fluid in the reaction section.

11. The electroplating method according to claim 1,
wherein a distance between the resist mask and the cathode is adjusted in accordance with at least one of time of the film formation, a current capacity to be applied to the anode or the cathode, and a thickness of the plated film to be formed.

12. The electroplating method according to claim 1,
wherein the anode and the resist mask have a pattern shape corresponding to a part of the cathode, and are arranged to face the cathode, and
the following steps are repeated plural times:
a step of setting the potential of the cathode to the negative potential to the anode in the state where the anode and the resist mask face the cathode, to form the metal plated film in a pattern state corresponding to a pattern of the resist mask on the surface of the cathode, and
a step of relatively moving the anode and the resist mask to the cathode.

13. An electroplating apparatus comprising:
a reaction tank constituted to store a plating solution;
an anode disposed in the reaction tank and having passages through which the plating solution passes;
a cathode disposed to face the anode;
a resist mask interposed between the anode and the cathode; and
a power source coupled to the anode and the cathode.

14. An electroplating apparatus comprising:
a reaction tank constituted to store a plating solution;
an anode and a cathode provided in the reaction tank and arranged to face each other via a mask member comprising a resist mask and a support layer having passages through which the plating solution flows; and
a power source coupled to the anode and the cathode.

15. The electroplating apparatus according to claim 13, further comprising:
an adjusting device constituted to adjust a distance between the cathode and the resist mask;
a plating solution supply section that supplies, to the reaction tank, the plating solution containing at least metal ions to be plated, an electrolyte and a surfactant, and
a control section that controls operations of the power source, the adjusting device and the plating solution supply section, and sets a potential of the cathode to a negative potential to the anode in a state where the anode and the cathode are arranged to face each other via the resist mask in the reaction tank in which the plating solution is stored, to form a metal plated film in a pattern state on the surface of the cathode.

16. The electroplating apparatus according to claim 13, further comprising:
a supercritical fluid supply section that supplies a supercritical fluid to the reaction tank; and
a control section that controls an operation of the supercritical fluid supply section.

17. The electroplating apparatus according to claim 13,
wherein the anode includes an anode plate formed on the surface of a metal layer,
the cathode includes a cathode plate having a wafer and a seed layer formed on the surface of the wafer,
the metal layer of the anode plate is coupled to a cathode of the power source, and
the seed layer of the cathode plate is coupled to an anode of the power source.

18. The electroplating apparatus according to claim 13, further comprising:
a pressurizing device that pressurizes the inside of the reaction tank to an atmospheric pressure or more.

19. A manufacturing method of a semiconductor device comprising:
arranging an anode having passages through which a plating solution flows and a cathode to face each other via a resist mask, in a reaction section storing the plating solution; and
setting a potential of the cathode to a negative potential to the anode, to form a metal plated film on the surface of the cathode.
